(19) United States
(12) Patent Application Publication
(10) Pub. No.: US 2024/0278383 A1
(43) Pub. Date: Aug. 22, 2024

(54) CHEMICAL MECHANICAL POLISHING APPARATUS AND CHEMICAL MECHANICAL POLISHING METHOD

(71) Applicant: SAMSUNG ELECTRONICS CO., LTD., SUWON-SI (KR)

(72) Inventors: Hwiyoung Jeong, Suwon-si (KR); Byoungho Kwon, Suwon-si (KR); Dongchan Kim, Suwon-si (KR)

(21) Appl. No.: 18/418,868

(22) Filed: Jan. 22, 2024

(30) Foreign Application Priority Data
Feb. 17, 2023 (KR) 10-2023-0021699

(51) Int. Cl. B24B 53/017; B24B 37/04; H01L 21/306

(52) U.S. Cl. CPC B24B 53/017; B24B 37/044; H01L 21/30625

(57) ABSTRACT

The inventive concept provides a chemical mechanical polishing apparatus including a polishing pad providing a flat main surface to which a slurry liquid having polishing particles is supplied and a conditioning disk on the main surface of the polishing pad. The conditioning disk can include a plurality of diamond particles that are positioned on a surface of the conditioning disk facing the main surface of the polishing pad, and wherein the plurality of diamond particles are terminated with specific elements on surfaces thereof, and a polarity of a zeta potential on the surface of the diamond particles is the same as that of a zeta potential on the polishing particles of the slurry liquid.

### CROSS-REFERENCE TO RELATED APPLICATION

This application is based on and claims priority under 35 U.S.C. § 119 to Korean Patent Application No. 10-2023-0021699, filed on Feb. 17, 2023, in the Korean Intellectual Property Office, the disclosure of which is incorporated by reference herein in its entirety.

### BACKGROUND

The inventive concept relates to a chemical mechanical polishing apparatus and a chemical mechanical polishing method, and more particularly, to a chemical mechanical polishing apparatus including a disk for conditioning a polishing pad and a chemical mechanical polishing method using the same.

A chemical mechanical polishing process may be used to planarize a wafer using a chemical mechanical polishing apparatus in manufacturing semiconductor devices. A polishing pad for polishing a surface of the wafer is generally provided in the chemical mechanical polishing apparatus, and a polishing pad conditioning device is provided for conditioning the surface of the polishing pad.

As the chemical mechanical polishing apparatus has been used, the cost for maintenance and management of the chemical mechanical polishing apparatus has increased. In particular, there is an increasing demand to reduce the cost of maintenance and management by increasing the replacement cycle of the pad conditioning disk that conditions the polishing pad.

### SUMMARY

The inventive concept provides a chemical mechanical polishing apparatus for preventing the wearing of a pad conditioning disk by making the polarity of the zeta potential on surfaces of diamond particles, that are provided on an upper surface of the pad conditioning disk, identical to the polarity of the zeta potential of a slurry liquid.

The inventive concept provides a chemical mechanical polishing method of making the polarity of a zeta potential on the surfaces of diamond particles, that are provided on an upper surface of the pad conditioning disk, identical to the polarity of the zeta potential of the slurry liquid, to thereby prevent the wearing of the pad conditioning disk.

According to an aspect of the inventive concept, there is provided a chemical mechanical polishing apparatus including a polishing pad providing a flat main surface to which a slurry liquid having polishing particles is supplied, and a conditioning disk on the main surface of the polishing pad, wherein the conditioning disk includes a plurality of diamond particles that are positioned on a surface of the conditioning disk facing the main surface of the polishing pad, wherein the plurality of diamond particles are terminated with specific elements on surfaces thereof, and a polarity of a zeta potential on the surfaces of the plurality of diamond particles is the same as a zeta potential on the polishing particles of the slurry liquid.

x.According to an aspect of the inventive concept, there is provided a chemical mechanical polishing apparatus, comprising a device body; a pivot arm operatively connected to the device body; a housing having an inner space at an end portion of the pivot arm distal from the device body; a head unit operatively connected to the housing, wherein the head unit includes, a motor in the inner space of the housing, wherein the motor includes a rotatable shaft; a disk holder operatively connected to a rotatable shaft of the motor; and a conditioning disk operatively connected to the disk holder; and a polishing pad having a main surface configured to receive a slurry liquid containing a plurality of polishing particles, wherein the conditioning disk includes a plurality of diamond particles positioned on a surface of the conditioning disk facing the main surface of the polishing pad, and wherein the plurality of diamond particles are terminated with hydrogen atoms on surfaces thereof.

According to an aspect of the inventive concept, there is provided a method of conditioning a polishing pad for performing a chemical mechanical polishing process, the method including supplying a slurry liquid containing polishing particles onto a flat main surface of a polishing pad, positioning a conditioning disk over the polishing pad in a direction perpendicular to the main surface of the polishing pad such that a lower surface of the conditioning disk overlaps the polishing pad, and moving the conditioning disk toward the main surface of the polishing pad to perform the conditioning against the polishing pad, wherein the conditioning disk includes a plurality of diamond particles positioned on a surface of the disk facing the main surface of the polishing pad, and wherein the plurality of diamond particles are terminated with hydrogen atoms on surfaces thereof.

### BRIEF DESCRIPTION OF THE DRAWINGS

Embodiments will be more clearly understood from the following detailed description taken in conjunction with the accompanying drawings in which:

FIG. 1 is a schematic perspective view illustrating a chemical mechanical polishing apparatus including a conditioning device, according to an embodiment;

FIG. 2 is a schematic perspective view illustrating a conditioning device, according to an embodiment;

FIG. 3 is a cross-sectional view taken along line X-X′ in FIG. 2;

FIG. 4 is a plan view illustrating a conditioning disk of the conditioning device, according to an embodiment;

FIGS. 5 and 6 are enlarged cross-sectional views illustrating the conditioning disk shown in FIG. 4, according to an embodiment;

FIGS. 7 and 8 are enlarged cross-sectional views illustrating the conditioning disk shown in FIG. 4, according to another embodiment;

FIG. 9 is a plan view illustrating a conditioning disk of a conditioning device according to another embodiment;

FIG. 10 is an enlarged cross-sectional view illustrating the conditioning disk shown in FIG. 9 according to another embodiment;

FIG. 11 is an enlarged cross-sectional view illustrating the conditioning disk shown in FIG. 9 according to another embodiment;

FIG. 12 is a graph showing the zeta potentials of various diamond particles on the conditioning disk according to a pH range;

FIG. 13 is a graph showing an effect of a chemical mechanical polishing apparatus according to an embodiment; and

FIG. 14 is a flowchart showing a chemical mechanical polishing method according to an embodiment.

### DETAILED DESCRIPTION

Hereinafter, embodiments of the inventive concept are described in detail with reference to the accompanying drawings. However, the inventive concept does not have to be configured as limited to the embodiments described below, and may be embodied in various other forms. The following embodiments are provided to describe aspects of the inventive concept to those skilled in the art.

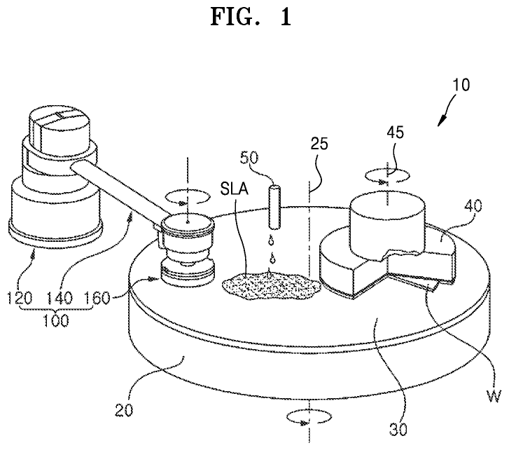

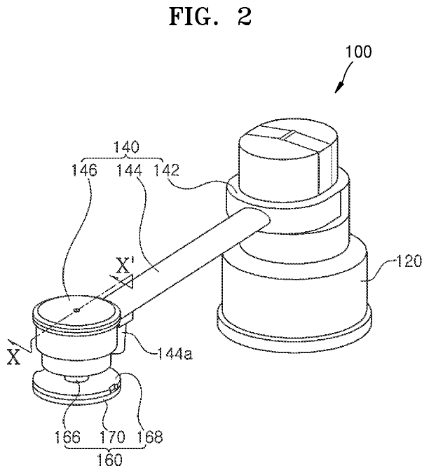

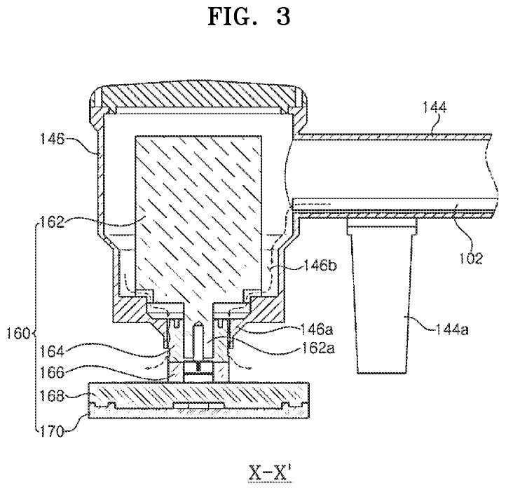

FIG. 1 is a schematic perspective view illustrating a chemical mechanical polishing apparatus including a conditioning device, according to an embodiment. FIG. 2 is a schematic perspective view illustrating a conditioning device according to an embodiment, and FIG. 3 is a cross-sectional view taken along line X-X′ in FIG. 2.

Referring to FIG. 1, a chemical mechanical polishing apparatus 10 may include, for example, a turn table 20, a wafer carrier 40, a slurry supply unit 50, and a conditioning device 100.

The turn table 20 may be rotatably installed on a rotating shaft, and an upper portion thereof may have a circular plate shape. The turn table 20 may be rotated in a preset direction, for example, in a counterclockwise direction around an axis of rotation 25. In addition, a polishing pad 30 may be provided on an upper surface of the turn table 20, and the polishing pad 30 may be, for example, a hard polyurethane pad. The polishing pad 30 can provide a flat main surface to which a slurry liquid having polishing particles is supplied.

The wafer carrier 40 may be circularly shaped, and may have a smaller diameter than the polishing pad 30. The wafer carrier 40 may have a diameter less than the radius of the polishing pad 30. The wafer carrier 40 can be configured to have a wafer W mounted on the wafer carrier 40. The wafer carrier 40 and wafer W mounted on the wafer carrier 40 may rotate about an axis 45, while in contact with the polishing pad 30. In an embodiment, when the planarization process is performed onto the wafer W, a chemical mechanical polishing process may be performed by using a slurry supplied from the slurry supply unit 50. The slurry supply unit 50 can be positioned in the chemical mechanical polishing apparatus 10 and provide slurry to the central portion of the turn table 20. Accordingly, the supplied slurry may be uniformly spread on the polishing pad 30 by centrifugal force.

The conditioning device 100 may be a device for conditioning a surface condition of the polishing pad 30 mounted on the turn table 20. The conditioning device 100 may polish the surface of the polishing pad 30 to maintain a surface roughness of the polishing pad 30 in an optimal state. For example, the conditioning device 100 may restore or maintain the surface roughness of the polishing pad 30 by polishing the polishing pad 30 with the wafer carrier 40, while the wafer W is polished or remains stationary.

When the chemical mechanical polishing (CMP) process is repeatedly performed, the surface of the polishing pad 30 can become smooth, which can rapidly reduce the polishing speed. The polishing precision and the polishing efficiency may deteriorate when polishing the wafer W. For at least these reasons, the conditioning device 100 may be utilized with the chemical mechanical polishing apparatus 10 to roughen the surface of the polishing pad 30, and to maintain the surface roughness of the polishing pad 30 in an optimal state. The polishing pad 30 may be roughened by the conditioning device 100 while the wafer W is polished or stationary with the wafer carrier 40, so that the surface roughness of the polishing pad 30 may be restored or maintained in the optimal state.

Referring to FIGS. 2 and 3, the conditioning device 100 may include, for example, a device body 120, a pivot arm 140, and a head unit 160.

The device body 120 may be positioned adjacent to the turn table 20. In an embodiment, the device body 120 may be provided with a main motor for rotating the pivot arm 140 in the circumferential direction. In addition, the device body 120 may be provided with an air cylinder to move the head unit 160 toward the polishing pad 30 or away from the polishing pad 30.

The conditioning device 100 may include a rotatable pivot arm 140, where the pivot arm 140 may rotate in a circumferential direction and be moved around the pivot center point 145 by the main motor and the air cylinder provided in the device body 120. The pivot arm 140 may be made of a metal material.

Referring to FIG. 2, the pivot arm 140 may be installed on the device body 120 and may rotate with respect to the pivot center point 145. For example, the pivot arm 140 may include an installation unit 142 combined with the device body 120, an arm unit 144 extending from the installation unit 142, and a housing 146 at an end of the arm unit 144 distal from the device body 120. In an embodiment, the pivot center point may be inside the installation unit 142.

In addition, the arm unit 144 may include a sensor holder 144a on which a sensor can be installed. A sensor in the sensor holder 144a may detect the presence of a polishing pad 30. For example, the sensor holder 144a may be positioned adjacent to the housing 146.

Referring to FIG. 3, the housing 146 may have an inner space. A narrow portion 146a may be provided at the lower portion of the housing 146 such that the narrow portion 146a has a diameter smaller than that of the upper portion of the housing 146. In addition, a fluid flow path 146b may be provided with the housing 146 and the fluid may be discharged to the outside of the housing 146 through the fluid flow path 146b. The arm unit 144 may have a hollow pipe shape and a fluid flow pipe 102, through which fluid can pass and wires may extend through the arm unit 144. The fluid flow pipe 102 can be in fluid communication with the fluid flow path 146b. Thus, the fluid supplied from the fluid flow pipe 102, which is positioned through the arm unit 144, may flow in the fluid flow path 146b. In addition, the fluid flowing in the fluid flow path 146b may include air, an inert gas (e.g., nitrogen, argon gas, etc.), or water. In addition, the fluid flowing in the fluid flow path 146b may be discharged to the outside of the housing 146 through a space defined by an inner surface of the narrow portion 146a in the housing 146 and an outer surface of a foreign matter preventor 164. Accordingly, foreign matter may be prevented from entering the housing 146 from the outside.

The head unit 160 may be at the end of the pivot arm 140, where the head unit 160 may extend from the housing 146. For example, the head unit 160 may include a rotating motor 162, a foreign matter preventor 164, a deformable member 166, a disk holder 168, and a conditioning disk 170.

The rotating motor 162 may be in the inner space of the housing 146 of the pivot arm 140. In addition, the rotating motor 162 may be provided with a rotating shaft 162a to which the foreign matter preventor 164 is connected. The rotating motor 162 may generate rotational force to rotate the foreign matter preventer 164, the deformable member 166, the disk holder 168, and the conditioning disk 170. The conditioning disk 170 may include a plurality of diamond particles that are positioned on a surface of the conditioning disk facing the main surface of the polishing pad 30. The polishing pad 30 can be between the conditioning disk 170 and the turn table 20, where a lower surface of the conditioning disk 170 can face the turn table 20.

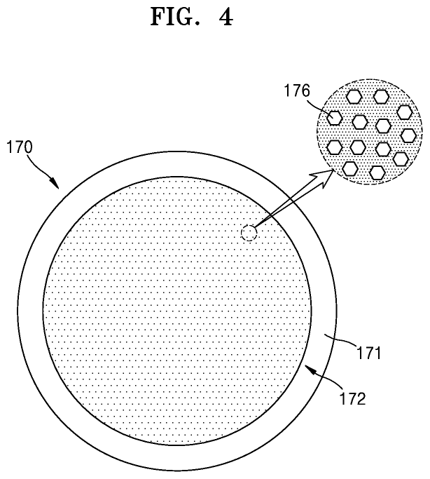

FIG. 4 is a plan view illustrating the conditioning disk 170 of the conditioning device 100, according to an embodiment.

As shown in FIG. 4 a polishing unit 172 may be provided on a support plate 171 that is provided on a surface of the conditioning disk 170. The surface of the support plate 171 may have a circular shape with a certain radius, and the polishing unit 172 may have a circular shape with a radius smaller than the radius of the support plate 171. The polishing unit 172 may have a circular shape and be included in a surface of the support plate 171. In an embodiment, the polishing unit 172 can be provided separately on the support plate 171, where the polishing unit 172 can be made of a metal, such as stainless steel. However, in some embodiments, the shape of the surface of the support plate 171 and the shape of the surface of the polishing unit 172 may not be limited to the circular shape.

In an enlarged view of the polishing unit 172, a plurality of diamond particles 176 may be provided on the surface of the polishing unit 172, where the plurality of diamond particles 176 may be densely arranged on the polishing unit 172. The plurality of diamond particles 176 may be arranged in a regular pattern on the surface of the polishing unit 172, where the plurality of diamond particles 176 may be affixed to the polishing unit 172 by an adhesive layer 174 on the surface of the polishing unit 172. The diamond particles 176 may be embedded in the adhesive layer 174.

When an area of the polishing unit 172 on which the plurality of diamond particles 176 are distributed is relatively large in comparison to the support plate 171, the fluidity of slurry may deteriorate. In contrast, when the area of the polishing unit 172 on which the plurality of diamond particles 176 are distributed is relatively small in comparison to the support plate 171, the conditioning effect against the polishing pad 30 may decrease. Therefore, the total area of the polishing unit 172 having the plurality of diamond particles 176 may be designed to be in a range of about 60% to about 70% of the total area of the support plate 171, and accordingly, the conditioning effect against the polishing pad 30 can be improved, while maintaining sufficient slurry fluidity. In an embodiment, the support plate 171 may include a solid material, such as ceramic or silicone.

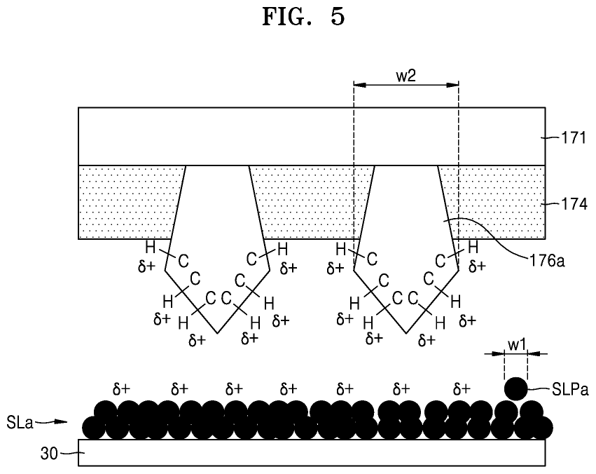

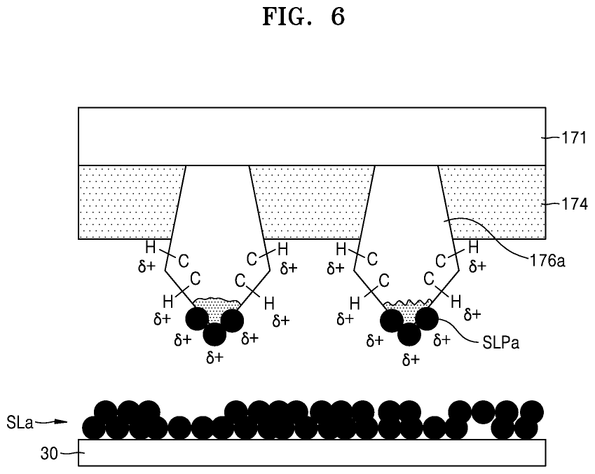

FIGS. 5 and 6 are enlarged cross-sectional views illustrating the conditioning disk shown in FIG. 4 according to an embodiment.

Referring to FIGS. 5 and 6, the conditioning disk 170 in FIG. 4 may include a plurality of diamond particles 176a that have a preset width and are distributed on the support plate 171. The plurality of diamond particles 176a shown in FIGS. 5 and 6 may be one of various embodiments of the plurality of diamond particles 176 shown in FIG. 4. For example, about 50,000 to about 60,000 of the diamond particles 176a having a maximal width w2 may be distributed on the conditioning disk 170 at intervals of about 300 micrometers. An adhesive layer 174 may be provided on the surface of the conditioning disk 170 to fix the plurality of diamond particles 176a onto the conditioning disk 170.

Referring to FIG. 1, a first slurry liquid SLa may be provided on a flat main surface of the polishing pad 30. The first slurry liquid SLa may include first polishing particles SLPa. The first slurry liquid SLa may include an oxidizing agent, a hydroxyl agent, a surfactant, a dispersant, and other catalysts. The dispersant may secure dispersion stability of the ceria molecule. The dispersant may include a nonionic polymer or a cationic organic compound. For example, the dispersant may include at least one organic material selected from the group consisting of ethylene oxide, ethylene glycol, glycol distearate, glycol monostearate, glycol polymerate, glycol ether, alcohol containing alkylamine, polymerate ether, a compound containing sorbitol, a nonionic surfactant, a vinyl pyrrolidone, a cellulose, and an ethoxylate-based compound. Specifically, the dispersant may include at least one organic material selected from the group consisting of diethylene glycol hexadecyl ether, decaethylene glycol hexadecyl ether, diethylene glycol octadecyl ether, eicosaethylene glycol octadecyl ether, diethylene glycol oley ether, decaethylene glycol oleyl ether, decaethylene glycol octadecyl ether, nonylphenol polyethylene glycol ether, ethylenediamine tetrakis(ethoxylate-block-propoxylate) tetrol, ethylenediamine tetrakis(propoxylate-block-ethoxylate) tetrol, polyethylene-block-poly(ethylene glycol), polyoxyethylene isooctylphenyl ether, polyoxyethylene octylphenyl ether, polyoxyethylene tridecyl ether, polyoxyethylene sorbitan tetraoleate, polyoxyethylene sorbitol hexaoleate, polyethylene glycol sorbitan monolaurate, polyoxyethylenesorbitan monolaurate, sorbitan monopalmitate, FS-300 nonionic fluorosurfactant, FSN nonionic fluorosurfactant, FSO nonionic ethoxylated fluorosurfactant, vinyl pyrrolidone, cellulose, 2,4,7,9-tetramethyl-5-decyne-4,7-diol ethoxylate), 8-methyl-1-nonanol propoxylate-block-ethoxylate, allyl alcohol 1,2-butoxylate-block-ethoxylate, polyoxyethylene branched nonylcyclohexyl ether, and polyoxyethylene isooctylcyclohexyl ether. For example, the dispersant may be mixed with the first slurry liquid SLa in a mixing ratio of about 0.5 wt % to about 1 wt %.

A polishing accelerator may include an aromatic-based amphipathic compound. The polishing accelerator may include 3-hydroxy-4-methyl-phenol anion, 3-hydroxy-4-hydrocyanomethyl-phenol anion, and a quinone compound, such as 4-methyl-benzene-1, 3-diol, kojic acid, maltol propionate, and maltol isobutyrate. The quinone compound may include at least one organic material selected from the group consisting of dienone, diol, and dienol (dienol anion) containing alkylbenzene diol, hydroxy group, and alkyl group, dienone, diol, dienol anion in which phenol anion and the alkyl group is linked by OXO, and dienone, diol, dienol anion containing hydroxyalkyl and benzene rings.

Here, the first slurry liquid SLa may include the first polishing particles SLPa and the first polishing particle SLPa may include silica, alumina, or ceria particles. The conditioning device 100 may perform a conditioning process of polishing the surface of the polishing pad 30 with the conditioning disk 170 on head unit 160 to which abrasives such as the plurality of diamond particles 176a are attached. The conditioning process can reproduce the roughness of the polishing pad 30, so that the surface roughness of the polishing pad 30 is maintained in an optimal state. A diameter of the first polishing particle SLPa may be in a range of about 50 micrometers to about 100 micrometers, and the maximal width, w2, of the diamond particles 176a may be in a range of about 200 mircometers to about 250 micrometers, where the diamond particles 176a may have a larger diameter than the first polishing particles SLPa.

The first polishing particle SLPa of the first slurry liquid SLa may have a positive zeta potential, where the zeta potential is a measure of the electrical potential in colloidal suspensions, and indicates the electrical charge of particles in a liquid medium.

The surfaces of the plurality of diamond particles 176a, which are arranged on the surface of the support plate 171 of the conditioning disk 170 opposite to the main surface of the polishing pad 30, may be terminated with hydrogen atoms, where surface bonds may be passivated by the hydrogen. The surface polarity of the diamond particles 176a may depend on the distribution of elements that are arranged on the surfaces of the diamond particles 176a. Being terminated with hydrogen atoms, the diamond particles 176a may have a positive zeta potential because the hydrogen has a positive polarity, whereas the carbon of the diamond particles 176a has a relatively negative polarity. The surface polarity of the diamond particles 176a may be changed by various surface treatment methods that may change the arrangement of hydrogen elements, such as high-temperature annealing, ion beam bombardment, and chemical treatment.

The zeta potential of the diamond particles 176a and the zeta potential of the first polishing particles SLPa of the first slurry liquid SLa may have the same positive potential. Because the zeta potential at the surfaces of the diamond particles 176a and the zeta potential of the first polishing particles SLPa of the first slurry liquid SLa have the same polarity, a repulsive force may be exerted between the diamond particles 176a and the first polishing particles SLPa. The repulsive force exerted between the diamond particles 176a and the first polishing particles SLPa can reduce abrasion between the diamond particles 176a and the first polishing particles SLPa. In the case that an attractive force is exerted between the diamond particles 176a and the first polishing particles SLPa, a great number of collisions may occur between the first polishing particles SLPa and the diamond particles 176a, and thus, the diamond particles 176a may be excessively worn out. The main cause of the excessive wear of the diamond particles 176a may be physical collisions between the first polishing particles SLPa of the first slurry liquid SLa and the diamond particles 176a. Therefore, when a repulsive force is exerted between the diamond particles 176a and first polishing particles SLPa, the physical collision may be sufficiently prevented and the excessive wear of the diamond particles 176a may also be reduced or prevented.

As shown in FIG. 6, when the conditioning process against the polishing pad 30 is continuously performed by the diamond particles 176a, the surfaces of the diamond particles 176a may be partially worn. In such a case, because no hydrogen elements are provided with the worn surfaces of the diamond particles 176a, the first polishing particles SLPa having positive charges may be attached to the worn surface of the diamond particles 176a. Even in this case, since the hydrogen elements are still provided with unworn surfaces of the diamond particles 176a, a repulsive force may be exerted between the unworn diamond particles 176a and the first polishing particles SLPb.

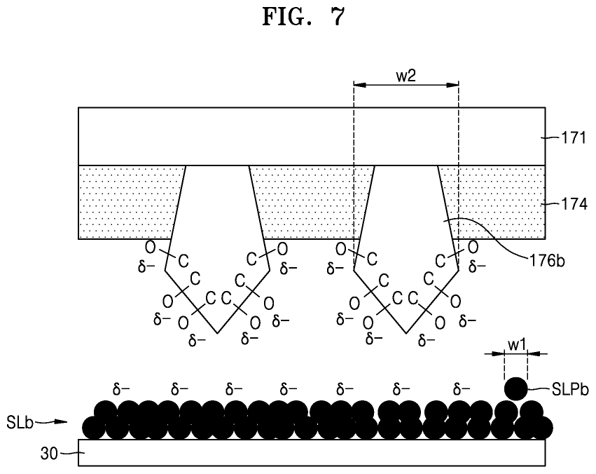

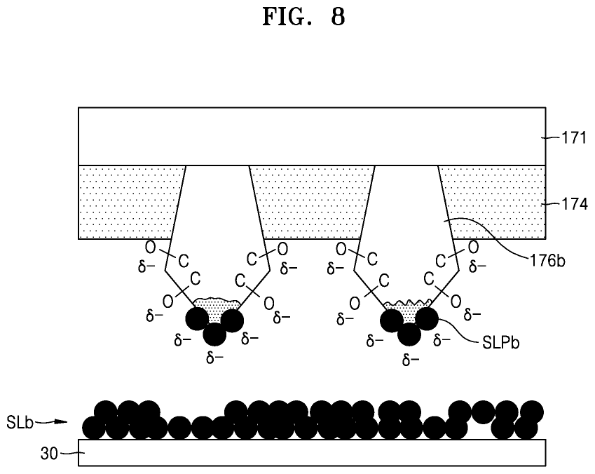

FIGS. 7 and 8 are enlarged cross-sectional views illustrating a conditioning disk shown in FIG. 4, according to another embodiment.

In FIGS. 7 and 8, the conditioning disk has substantially the same structures as the conditioning disk shown in FIGS. 5 and 6, except for the type of element on the surfaces of a plurality of diamond particles 176b. Specifically, the zeta potential of the surfaces of the diamond particles 176b shown in FIGS. 7 and 8 may be a negative zeta potential. In addition, compared to the first slurry liquid SLa shown in FIGS. 5 and 6, second polishing particles SLPb of a second slurry liquid SLb shown in FIGS. 7 and 8 may have a negative zeta potential.

The second slurry liquid SLb may be provided on the flat main surface of the polishing pad 30. The second slurry liquid SLb may include second polishing particles SLPb having a negative zeta potential.

The surfaces of the diamond particles 176b, which are on a surface of the support plate 171 of the conditioning disk 170 opposite to the main surface of the polishing pad 30, may be terminated with oxygen atoms, where surface bonds may be passivated by the oxygen. However, the plurality of the diamond particles 176b terminated with oxygen atoms is an example embodiment of the case that the diamond particles 176b are terminated with a negative zeta potential on the surface thereof. Therefore, other elements besides oxygen may be used to passivate the the diamond particles 176b and produce a negative zeta potential. The polarity of the surfaces of the diamond particles 176b may depend on the distribution of the elements that are arranged on the surface of the diamond particles 176b. The diamond particles 176b of which the surfaces are terminated by oxygen elements may have a negative zeta potential. This is because oxygen has a negative polarity, whereas carbon of the diamond particles 176b has a relatively positive polarity. The surface polarity of the diamond particles 176b may be changed by various surface treatment methods that may change the arrangement of oxygen atoms, such as high-temperature annealing, ion beam bombardment, and chemical treatment.

The zeta potential on the surfaces of the diamond particles 176b and the zeta potential on the second polishing particles SLPb of the second slurry liquid SLb may have the same negative potential. Since the zeta potential on the surfaces of the diamond particles 176b and the zeta potential on the second polishing particles SLPb of the second slurry liquid SLb have the same zeta potential, a repulsive force may be exerted between the diamond particles 176b and the second polishing particles SLPb. In case that an attractive force is exerted between the diamond particles 176b and the second polishing particles SLPb, a great number of collisions may occur between the second polishing particles SLPb and the diamond particles 176b, and thus, the diamond particles 176b may be excessively worn out. The main cause of the excessive wear of the diamond particles 176b may be physical collisions between the second polishing particles SLPb of the second slurry liquid SLb and the diamond particles 176b. Therefore, when a repulsive force is exerted between the diamond particles 176b and second polishing particles SLPb, physical collisions may be sufficiently reduced or prevented, and the excessive wear of the diamond particles 176b may also be reduced or prevented.

As shown in FIG. 8, when the conditioning process against the polishing pad 30 is continuously performed by the diamond particles 176b, the surfaces of the diamond particles 176b may be partially worn. In such a case, since passivating elements may no longer be on the worn surfaces of the diamond particles 176b, the second polishing particles SLPb having negative charges may be attached to the worn surfaces of the diamond particles 176b. Even in this case, because the oxygen atoms can still be on unworn surfaces of the diamond particles 176b, a repulsive force may be exerted between the unworn portion of the diamond particles 176b and the second polishing particles SLPb.

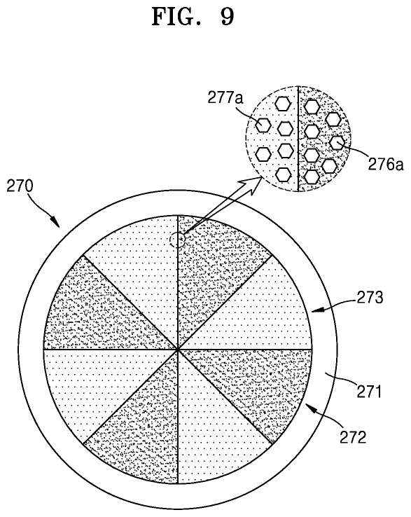

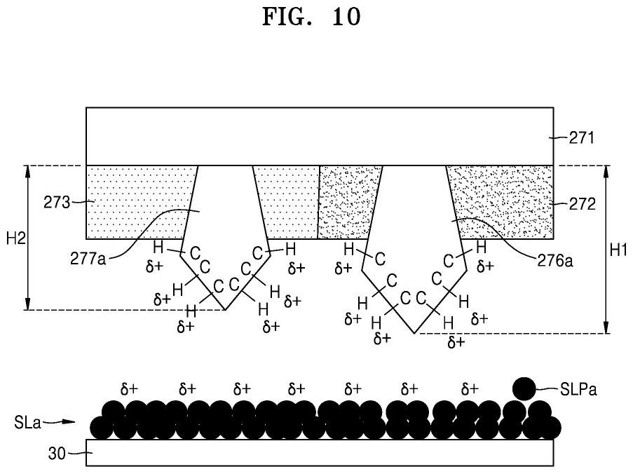

FIG. 9 is a plan view illustrating a conditioning disk of the conditioning device according to another embodiment. FIG. 10 is an enlarged cross-sectional view illustrating the conditioning disk shown in FIG. 9 according to another embodiment.

Referring to FIGS. 9 and 10, a first polishing unit 272 and a second polishing unit 273 may be provided on a support plate 271 that is provided on a surface of a conditioning disk 270. The surface of the support plate 271 may have a circular shape with a certain radius, and the first polishing unit 272 and the second polishing unit 273 may each have a wedge (or fan) shape with a radius smaller than the radius of the support plate 271. The first polishing unit 272 and the second polishing unit 273 may be alternately positioned in a form of the circular shape, so that a plurality of first polishing units 272 and a plurality of second polishing units 273 may be provided on the support plate 271. However, the surface shape of the support plate 271 and the overall shape of the combination of the first polishing units 272 and the second polishing units 273 are not limited to the circular shape depending on the embodiment. In FIG. 9, the size ratio of the first polishing units 272 and the second polishing units 273 is shown to be about 50% on the support plate 271, respectively, but the size ratio of the first polishing units 272 and the second polishing units 273 on the support plate 271 may also vary depending on the embodiment.

In an enlarged view of the boundary between the neighboring first and second polishing units 272 and 273, a plurality of diamond particles 276a and 277a may be arranged on each of the surfaces of the first polishing unit 272 and the second polishing unit 273, respectively. The plurality of diamond particles 276a and 277a may be arranged in a regular pattern on the surface of the first polishing units 272 and the second polishing units 273, respectively. In an embodiment, the conditioning disk 270 may be configured in such a structure that a plurality of the first and second polishing units 272 and 273 are separately provided on the support plate 271 that is made of metal such as stainless steel and the plurality of diamond particles 276a and 277a may be densely arranged in the first and second polishing units 272 and 273.

In FIG. 9, the conditioning disk 270 has substantially the same structures as the conditioning disk 170 shown in FIG. 4 or similar structures thereto, except that the first and second polishing units 272 and 273 are provided.

Referring to FIG. 10, the conditioning disk 270 may include the first and second polishing units 272 and 273 in such a configuration that the plurality of first polishing units 272, which include the first diamond particles 276a having a first average height H1, are alternately and rotatably arranged with the plurality of second polishing units 273, which include the second diamond particles 277a having a second average height H2, in a form of the circular shape having the center on the surface thereof. The first diamond particles 276a in the first polishing unit 272 and the second diamond particles 277a in the second polishing unit 273 may include the same material having the same composition. The first average height H1, which is a protruding height of the first diamond particles 276a from the surface of the support plate 271, may be different from the second average height H2, which is a protruding height of the second diamond particles 277a from the surface of the support plate 271. In this case, the first average height H1 and the second average height H2 may be in a range of about 10% to about 20% of the total average height of the first and second diamond particles 276a and 277a that are arranged on the surface of the support plate 271.

The first polishing particles SLPa of the first slurry liquid SLa, which are provided on the flat main surface of the polishing pad 30, may have a positive zeta potential. In addition, the first and second diamond particles 276a and 277a, which are on the surface of the support plate 271 of the conditioning disk 270 opposite to the main surface of the polishing pad 30, may be terminated by hydrogen elements.

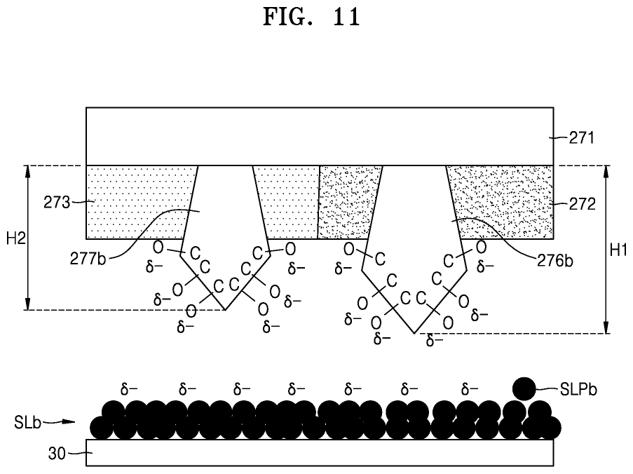

FIG. 11 is an enlarged cross-sectional view illustrating the conditioning disk shown in FIG. 9 according to another embodiment.

There are differences in that the second slurry liquid SLb and a plurality of diamond particles 276b and 277b shown in FIG. 11 have zeta potential polarity that is different from that of the first slurry liquid SLa and the first and second diamond particles 276a and 277a shown in FIG. 10. In FIG. 11, the same reference numerals denote the same elements in FIG. 10 and any further descriptions on the same elements are omitted.

The element terminated on the surfaces of the plurality of diamond particles 276b and 277b shown in FIG. 11 may be different from the element terminated on the surfaces of the first and second diamond particles 276a and 277a shown in FIG. 10. Specifically, the zeta potential of the surfaces of the diamond particles 176b shown in FIGS. 7 and 8 may be a negative potential. In addition, the second polishing particle SLPb of the second slurry liquid SLb shown in FIGS. 7 and 8 may have a negative zeta potential as compared with the first slurry liquid SLa shown in FIGS. 5 and 6.

The surfaces of the diamond particles 276b and 277b, which are on the surface of the support plate 271 of the conditioning disk 270 opposite to the main surface of the polishing pad 30, may be terminated with oxygen elements. However, the plurality of the diamond particles 276b and 277b terminated with oxygen elements is an example embodiment of the case that the diamond particles 276b and 277b are terminated with a negative zeta potential on the surface thereof. Therefore, an element terminated to the diamond particles 276b and 277b having a negative zeta potential is not limited to oxygen.

The zeta potential on the surfaces of the diamond particles 276b and 277b and the zeta potential on the polishing particles SLPb of the slurry liquid SLb may have the same negative potential. Since the zeta potential on the surfaces of the diamond particles 276b and 277b and the zeta potential on the second polishing particles SLPb of the second slurry liquid SLb have the same zeta potential, a repulsive force may be exerted between the diamond particles 276b and 277b and the second polishing particles SLPb. Therefore, when a repulsive force is exerted between the diamond particles 276b and 277b and the second polishing particles SLPb, physical collisions may be sufficiently prevented and the excessive wear of the diamond particles 276b and 277b may also be prevented.

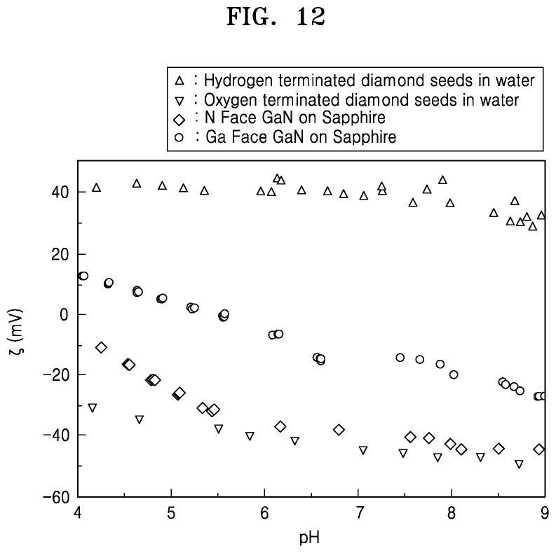

FIG. 12 is a graph showing the zeta potentials of various diamond particles on the conditioning disk according to a pH range.

Referring to FIG. 12, the horizontal axis of the graph in FIG. 12 represents the pH of the slurry liquid and the vertical axis of the graph represents the zeta potential of the diamond particles. A pH of the slurry liquid can be in a range of about 3 to about 10. As shown in FIG. 12, when the pH of the slurry liquid is in a range of about 4 to about 9, the zeta potential on the surfaces of the hydrogen-terminated diamond particles is in a range of about 30 millivolts (mV) to about 50 mV. In addition, when the pH of the slurry liquid is in a range of about 4 to about 9, the zeta potential on the surfaces of the oxygen-terminated diamond particles is in a range of about −30 mV to about 50 mV. Therefore, the diamond particles with hydrogen-terminated surfaces may have a positive zeta potential, and in this case, a repulsive force may be exerted between the diamond particles and the slurry liquid having particles with a positive zeta potential. In addition, the diamond particles with oxygen-terminated surfaces may have a negative zeta potential, and in this case, a repulsive force may be exerted between the diamond particles and the slurry liquid having particles with a negative zeta potential.

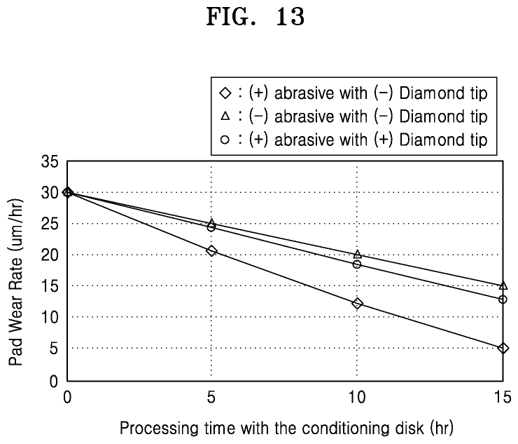

FIG. 13 is a graph showing an effect of a chemical mechanical polishing apparatus according to an embodiment.

Referring to FIG. 13, the horizontal axis of the graph represents a working time of the conditioning disk and the vertical axis of the graph represents the abrasion ratio of the polishing pad per hour. The graph shows that the abrasion ratio of the polishing pad decreases sharply as the working time of the conditioning disk increases when the diamond particles having negative zeta potential are used in the slurry liquid (polishing agent) having positive zeta potential. When an attractive force is exerted between the polishing particles of the slurry liquid having a positive zeta potential and the diamond particles having a negative zeta potential, the diamond particles may be well worn. Thus, the conditioning process by the diamond particles against the polishing pad may not be sufficiently performed due to the frequent wearing of the diamond particles, which causes the decrease of the abrasion ratio of the polishing pad.

The graph also shows that the abrasion ratio of the polishing pad decreases slowly as the working time of the conditioning disk increases when the diamond particles having positive zeta potential are used in the slurry liquid (polishing agent) having positive zeta potential. The same is true even when the diamond particles having a negative zeta potential are used in the slurry liquid (polishing agent) having a negative zeta potential. When the slurry liquid (polishing agent) and the diamond particles have the same polarity of zeta potential, a repulsive force may be exerted between the polishing particles of the slurry liquid (polishing agent) and the diamond particles, to thereby control the occurrence of the wearing of the diamond particles. Therefore, as the diamond particles are hardly worn, the conditioning process against the polishing pad may be performed sufficiently well, and thus, the abrasion ratio of the polishing pad decreases relatively slowly.

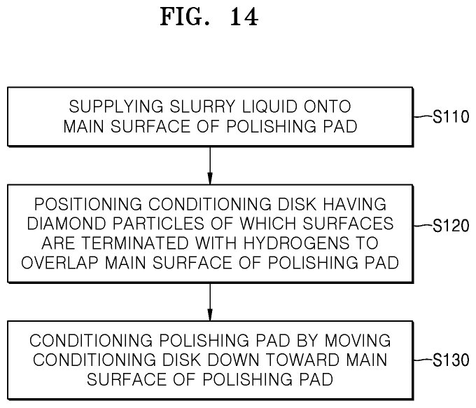

FIG. 14 is a flowchart showing a chemical mechanical polishing method according to an embodiment. For convenience of description, the chemical mechanical polishing method is described with reference to FIGS. 1 to 5 as well as to FIG. 14.

Referring to operation S130 in FIG. 14, a chemical mechanical polishing method according to an embodiment may include an operation of supplying the slurry liquid SLa onto the main surface of the polishing pad 30. In this case, the slurry liquid SLa may include the polishing particles SLPa having a positive zeta potential. In various embodiments, the pH of the slurry liquid SLa may be in a range of about 3 to about 10.

Referring to operation S120 in FIG. 14, the chemical mechanical polishing method may include an operation of positioning the conditioning disk 170 having the diamond particles 176a of which the surfaces are terminated with hydrogens to overlap the main surface of the polishing pad 30. Particularly, the surfaces of the diamond particles 176a may have a positive zeta potential in a range of about 20 mV to about 60 mV.

Referring to operation S130 in FIG. 14, the chemical mechanical polishing method may include an operation of conditioning the polishing pad 30 by moving the conditioning disk 170 down toward the main surface of the polishing pad 30.

Embodiments are disclosed in the drawings and specification as described above. Embodiments have been described using specific terms in the present specification, but this is used only for the purpose of describing the technical idea of the this disclosure and is not used to limit the scope of the this disclosure described in the meaning or patent claims. Therefore, those of ordinary skill in the art will understand that various modifications and equal other embodiments are possible from this. Therefore, the true technical scope of protection of the present disclosure should be determined by the technical idea of the appended claims.

While the inventive concept has been particularly shown and described with reference to embodiments thereof, it will be understood that various changes in form and details may be made therein without departing from the spirit and scope of the following claims.

What is claimed is:

1. A chemical mechanical polishing apparatus comprising:
a polishing pad providing a flat main surface to which a slurry liquid having polishing particles is supplied; and
a conditioning disk on the main surface of the polishing pad,
wherein the conditioning disk includes a plurality of diamond particles that are positioned on a surface of the conditioning disk facing the main surface of the polishing pad, wherein the plurality of diamond particles are terminated with specific elements on surfaces thereof, and
a polarity of a zeta potential on the surfaces of the plurality of diamond particles is the same as a zeta potential on the polishing particles of the slurry liquid.

2. The chemical mechanical polishing apparatus of claim 1, wherein the specific elements include hydrogen atoms, and
both of the polarity of the zeta potential on the surfaces of the plurality of diamond particles and the polarity of the zeta potential on the polishing particles of the slurry liquid are positive.

3. The chemical mechanical polishing apparatus of claim 1, wherein the specific elements are oxygen atoms, and
both of the polarity of the zeta potential on the surfaces of the plurality of diamond particles and the polarity of the zeta potential on the polishing particles of the slurry liquid are negative.

4. The chemical mechanical polishing apparatus of claim 1, wherein the polishing particles in the slurry liquid include silica, alumina, or ceria particles.

5. The chemical mechanical polishing apparatus of claim 4, wherein a diameter of the polishing particle is in a range of about 50 micrometers to about 100 micrometers, and
a maximal width of each of the plurality of diamond particles is in a range of about 200 micrometers to about 250 micrometers.

6. The chemical mechanical polishing apparatus of claim 1, wherein a pH of the slurry liquid is in a range of about 3 to about 10.

7. The chemical mechanical polishing apparatus of claim 1, wherein the plurality of diamond particles are arranged in a regular pattern on the surface of the conditioning disk.

8. The chemical mechanical polishing apparatus of claim 1, wherein the plurality of diamond particles individually protrude from the surface of the conditioning disk and have a plurality of different heights.

9. The chemical mechanical polishing apparatus of claim 8, wherein a height difference of the plurality of protruded heights is in a range of 10% to 20% of an average height of the plurality of diamond particles.

10. The chemical mechanical polishing apparatus of claim 1, wherein the plurality of diamond particles include first diamond particles having a first average height; and
second diamond particles having a second average height, wherein the second average height is less than the first average height.

11. A chemical mechanical polishing apparatus, comprising:
a device body;
a pivot arm operatively connected to the device body;
a housing having an inner space at an end portion of the pivot arm distal from the device body;
a head unit operatively connected to the housing, wherein the head unit includes,
a motor in the inner space of the housing, wherein the motor includes a rotatable shaft;
a disk holder operatively connected to a rotatable shaft of the motor; and
a conditioning disk operatively connected to the disk holder; and
a polishing pad having a main surface configured to receive a slurry liquid containing a plurality of polishing particles,
wherein the conditioning disk includes a plurality of diamond particles positioned on a surface of the conditioning disk facing the main surface of the polishing pad, and wherein the plurality of diamond particles are terminated with hydrogen atoms on surfaces thereof.

12. The chemical mechanical polishing apparatus of claim 11, wherein surfaces of the plurality of diamond particles terminated by the hydrogen elements have a positive zeta potential polarity, and the polishing particles of the slurry liquid have a positive zeta potential polarity.

13. The chemical mechanical polishing apparatus of claim 12, wherein the zeta potential is in a range of about 20 mV to about 60 mV.

14. The chemical mechanical polishing apparatus of claim 11, wherein a pH of the slurry liquid is in a range of about 3 to about 10.

15. The chemical mechanical polishing apparatus of claim 11, wherein the polishing particles in the slurry liquid include silica, alumina, or ceria particles.

16. The chemical mechanical polishing apparatus of claim 15, wherein a diameter of the polishing particle is in a range of about 50 micrometers to 100 micrometers, and
a maximal width of each of the plurality of diamond particles is in a range from about 200 micrometers to about 250 micrometers.

17. A method of conditioning a polishing pad for performing a chemical mechanical polishing process, the method comprising:
supplying a slurry liquid containing polishing particles onto a flat main surface of a polishing pad;
positioning a conditioning disk over the polishing pad in a direction perpendicular to the main surface of the polishing pad, wherein a lower surface of the conditioning disk overlaps the polishing pad; and
moving the conditioning disk toward the main surface of the polishing pad to perform the conditioning against the polishing pad,
wherein the conditioning disk includes a plurality of diamond particles positioned on a surface of the disk facing the main surface of the polishing pad, and wherein the plurality of diamond particles are terminated with hydrogen atoms on surfaces thereof.

18. The method of claim 17, wherein the polishing particles of the slurry liquid have a positive zeta potential, and
the surfaces of the plurality of diamond particles terminated with the hydrogen atoms have a positive zeta potential.

19. The method of claim 18, wherein the zeta potential is in a range of about 20 mV to about 60 mV.

20. The method of claim 17, wherein a pH of the slurry liquid is in a range of about 3 to about 10.
